(19) United States
(12) Patent Application Publication
(10) Pub. No.: US 2007/0241422 A1
(43) Pub. Date: Oct. 18, 2007

(54) Seal-Ring Structure for System-Level ESD Protection

(76) Inventor: Shiao-Shien Chen, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/423,456

(22) Filed: Jun. 12, 2006

(30) Foreign Application Priority Data
Apr. 17, 2006 (TW) 095113674

(51) Int. Cl. H01L 29/00

(52) U.S. Cl. 257/528

(57) ABSTRACT

A seal-ring structure is formed on a p-substrate that is coupled to a first voltage terminal. The seal-ring structure includes an n-well, a first metal layer, a second metal layer, a first capacitor, a poly-silicon layer, and a second capacitor. The n-well is formed on the p-substrate and coupled to a second voltage terminal. The first metal layer is sited on a first dielectric layer on the p-substrate and connected to the p-substrate through a plurality of contacts. The second metal layer is sited on a second dielectric layer on the first metal layer and connected to the n-well through a plurality of contacts. The first capacitor is formed between the first metal layer and the second metal layer. The poly-silicon layer is formed between the first metal layer and the n-well. The second capacitor is formed between the poly-silicon layer and the n-well.

### BACKGROUND OF THE INVENTION

1. Field of the Invention

The present invention relates to a seal-ring structure with system-level ESD protection, and more particularly, to a seal-ring structure having a poly-silicon layer between the first metal layer and the n-well to increase system-level ESD protection.

2. Description of the Prior Art

Semiconductor manufactures have been shrinking transistor size in integrated circuits (IC) to improve chip performance. This has resulted in increased speed and device density. The use of low dielectric constant materials causes this industry another problem in that the adhesion ability, either at the interface between two adjacent low dielectric constant layers or at the interface between a low dielectric constant layer and a dissimilar dielectric layer, is somewhat inadequate to meet the requirements in the subsequent wafer treatment processes such as wafer dicing. Wafer dicing is a process typically performed to mechanically cut a semiconductor wafer into a number of individual IC chip.

It has been found that the so-called “interface delaminating” or “chip cracking” phenomenon occurs between low dielectric constant layers during or after the wafer dicing process is performed, causing performance degradation of the IC chips.

Furthermore, electrostatic discharge (ESD) is a common phenomenon appearing in semiconductor manufacturing. Electric charges are brought into integrated circuits through input/output pins in an ultra-short time to damage internal circuits of ICs. Therefore, ESD problems become a bottleneck to improved efficiency of integrated circuits.

Please refer to FIG. 1. FIG. 1 is a diagram of an integrated circuit chip 10 with seal-ring structure according to the prior art. The integrated circuit chip 10 includes a plurality of internal wafers 12. A circle of seal-ring structure 14 is added around each internal wafer 12 to protect the internal wafer 12.

Please refer to FIG. 2 that is a cross-sectional drawing of a seal-ring structure 20 according to the prior art. The prior art utilizes a p-substrate 22 as the base of the seal-ring structure 20. A p+ highly doped region 23 is formed on the p-substrate 22 and connected to a first voltage terminal V_{SS}. A first metal layer M1 is sited on a first dielectric layer DL1 on the p+ highly doped region 23 and connected to the p+ highly doped region 23 through a plurality of contacts 25. A second metal layer M2 is sited on a second dielectric layer DL2 on the first metal layer M1 and connected to the first metal layer M1 through a plurality of vias 27. To reason by analogy, a third metal layer M3 is sited on a third dielectric layer DL3 on the second metal layer M2 and connected to the second metal layer M2 through the plurality of vias 27. A fourth metal layer M4 is sited on a fourth dielectric layer DL4 on the third metal layer M3 and connected to the third metal layer M3 through the plurality of vias 27. The seal-ring structure 20 further includes a dielectric isolation layer 28 that is formed by a chemical vapor deposition (CVD) process. The dielectric isolation layer 28 is silicon dioxide (SiO₂). The first metal layer M1, the second metal layer M2, the third metal layer M3, and the fourth metal layer M4 are all connected to the first voltage terminal V_{SS}.

System-level ESD protection of seal-ring structure applications are already disclosed in U.S. Pat. No. 6,815,821 “Method of Fabricating Seal-ring Structure with ESD Protection”, U.S. Pat. No. 5,998,245 “Method for Making Seal-ring Structure with ESD Protection Device”, and TW patent No. 521,423 “Seal-ring Structure with system ESD Protection”. In U.S. Pat. No. 6,815,821, the method of work is connecting the p-substrate to a voltage terminal V_{SS}. An n+ highly doped region is formed on the p-substrate and a plurality of metal layers are sited on the n+ highly doped region and connected to the n+ highly doped region through a plurality of contacts. Each of the plurality of metal layers is connected to a voltage terminal V_{DD}. Then there is an equivalent diode formed between the voltage terminal V_{DD} and the voltage terminal V_{SS} to lead out static charges. This improves security capability.

In U.S. Pat. No. 5,998,245, the method of work is forming an n+ highly doped region and a p+ highly doped region on an n-substrate. A first metal layer is sited on the n+ highly doped region, and a second metal layer is sited on the p+ highly doped region. The first metal layer is connected to a voltage terminal V_{DD}, and the second metal layer is connected to a voltage terminal V_{SS}. Two protection diodes with big capacitance are formed between the voltage terminal V_{DD} and the voltage terminal V_{SS} to provide ESD protection. The invention of U.S. Pat. No. 5,998,245 is also suitable for a p-substrate.

In TW patent No. 521,423, the method of work is forming a source and a drain that comprise n+ dope on a p-substrate. A poly-silicon layer is formed on a dielectric isolation layer on the p-substrate as a gate to construct a capacitor. A first metal layer is sited on the p-substrate and connected to the source and the drain through a plurality of contacts. The first metal layer is connected to a high voltage level V_{DD}. A second metal layer is sited on the first metal layer and a transition metal layer is sited on the same plane of the first metal layer. The second metal layer is connected to the transition metal layer through a plurality of vias and connected to the gate through the plurality of contacts. The second metal layer is connected to a low voltage level V_{SS}. There is a capacitor formed between the gate and the source/drain which equals supplying a capacitor between the high voltage level V_{DD} and the voltage level V_{SS}.

When dealing with wafer dicing presently, a circle of seal-ring structure is added around integrated circuits to protect the internal wafer. The traditional seal-ring structures only prevent an IC chip from being damaged by a mechanical knife and not ESD protection due to its simple construction. Even though seal-ring structures after improvement can provide ESD protection, the effect is not good.

### SUMMARY OF THE INVENTION

The claimed invention provides a seal-ring structure formed on a p-substrate, which is coupled to a first voltage terminal. The seal-ring structure includes an n-well, a first metal layer, a second metal layer, a first capacitor, a poly-silicon layer, and a second capacitor. The n-well is formed on the p-substrate and coupled to a second voltage terminal. The first metal layer includes a portion of a block sited on a first dielectric layer on the p-substrate and connected to the p-substrate through a plurality of contacts. The second metal layer includes a portion of a block sited on a second dielectric layer on the first metal layer and connected to the n-well through a plurality of contacts. The first capacitor is formed between the first metal layer and the second metal layer. The poly-silicon layer is formed between the first metal layer and the n-well. The second capacitor is formed between the poly-silicon layer and the n-well. The seal-ring structure further includes an n-buried layer and a third capacitor. The n-buried layer is formed between the n-well and the p-substrate. The third capacitor formed between the n-buried layer and the p-substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an integrated circuit chip with seal-ring structure according to the prior art.

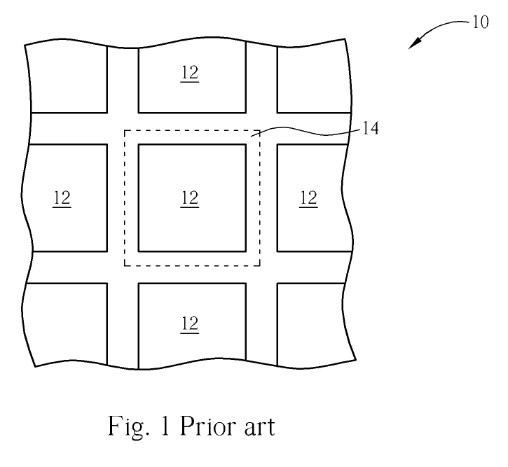

FIG. 2 is a cross-sectional drawing of a seal-ring structure according to the prior art.

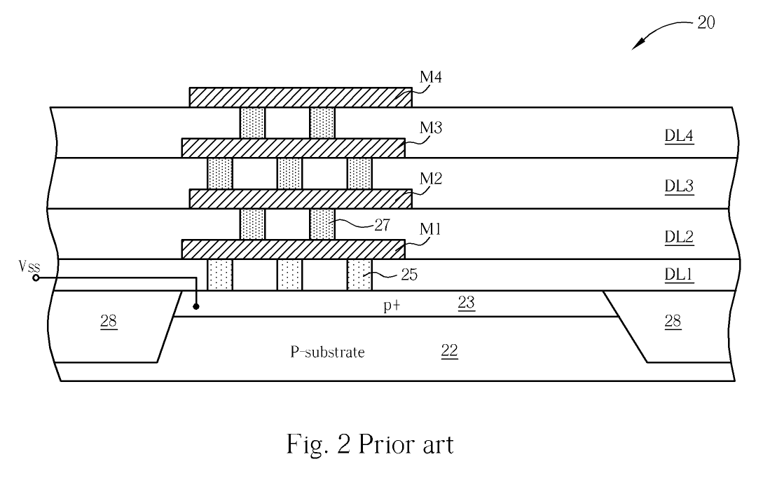

FIG. 3 is a cross-sectional drawing of a seal-ring structure according to the present invention.

FIG. 4 is a cross-sectional drawing of another seal-ring structure according to the present invention.

FIG. 5 is a diagram of an integrated circuit chip with a seal-ring structure according to the present invention.

### DETAILED DESCRIPTION

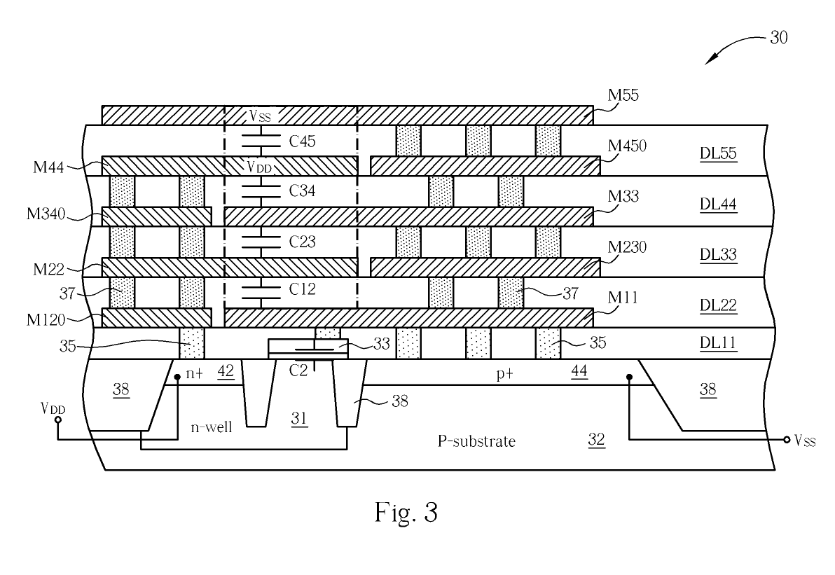

Please refer to FIG. 3 that is a cross-sectional drawing of a seal-ring structure 30 according to the present invention. In the embodiment, a p-substrate 32 is utilized as the base of the seal-ring structure 30. An n-well 31 is formed on the p-substrate 32. An n+ highly doped region 42 is formed on the n-well 31 and connected to a second voltage terminal V_{DD}. The seal-ring structure 30 further includes a p+ highly doped region 44 formed on the p-substrate 32 and connected to a first voltage terminal V_{SS}. A first metal layer M11 includes a portion of a block sited on a first dielectric layer DL11 on the p+ highly doped region 44 and connected to the p+ highly doped region 44 through a plurality of contacts 35. The doped concentration of the p+ highly doped region 44 is greater than the doped concentration of the p-substrate 32. A second metal layer M22 includes a portion of a block sited on a second dielectric layer DL22 on the first metal layer M11. A transition metal layer M120 is sited on the same plane of the first metal layer M11. The second metal layer M22 is connected to the transition metal layer M120 through a plurality of vias 37, and the transition metal layer M120 is connected to the n+ highly doped region 42 through the plurality of contacts 35. The doped concentration of the n+ highly doped region 42 is greater than the doped concentration of the n-well 31. A capacitor C12 is formed between the first metal layer M11 and the second metal layer M22.

A third metal layer M33 includes a portion of a block sited on a third dielectric layer DL33 on the second metal layer M22. A transition metal layer M230 is sited on the same plane of the second metal layer M22. The third metal layer M33 is connected to the transition metal layer M230 through the plurality of vias 37. The transition metal layer M230 is connected to the first metal layer M11 through the plurality of vias 37. A capacitor C23 is formed between the second metal layer M22 and the third metal layer M33. A fourth metal layer M44 includes a portion of a block sited on a fourth dielectric layer DL44 on the third metal layer M33. A transition metal layer M340 is sited on the same plane of the third metal layer M33. The fourth metal layer M44 is connected to the transition metal layer M340 through the plurality of vias 37. The transition metal layer M340 is connected to the second metal layer M22 through the plurality of vias 37. A capacitor C34 is formed between the third metal layer M33 and the fourth metal layer M44. A fifth metal layer M55 includes a portion of a block sited on a fifth dielectric layer DL55 on the fourth metal layer M44. A transition metal layer M450 is sited on the same plane of the fourth metal layer M44. The fifth metal layer M55 is connected to the transition metal layer M450 through the plurality of vias 37. The transition metal layer M450 is connected to the third metal layer M33 through the plurality of vias 37. A capacitor C45 is formed between the fourth metal layer M44 and the fifth metal layer M55.

Please continue to refer to FIG. 3. A poly-silicon layer 33 is formed between the first metal layer M11 and the n-well 31. A second capacitor C2 is formed between the poly-silicon layer 33 and the n-well 31. The seal-ring structure 30 further includes a dielectric isolation layer 38 that is formed between the n-well 31 and the p-substrate 32 by a chemical vapor deposition (CVD) process. The dielectric isolation layer 38 is silicon dioxide (SiO₂). The first voltage terminal V_{SS} is the lowest voltage of the seal-ring structure 30, and the second voltage terminal V_{DD} is the highest voltage of the seal-ring structure 30. The first metal layer M11, the third metal layer M33, the fifth metal layer M55, the transition metal layer M230, and the transition metal layer M450 are connected to the first voltage terminal V_{SS}. The second metal layer M22, the fourth metal layer M44, the transition metal layer M120, and the transition metal layer M340 are connected to the second voltage terminal V_{DD}. The first metal layer M11, the second metal layer M22, the third metal layer M33, the fourth metal layer M44, the fifth metal layer M55, and the transition metal layers M120, M230, M340, and M450 include gold and copper.

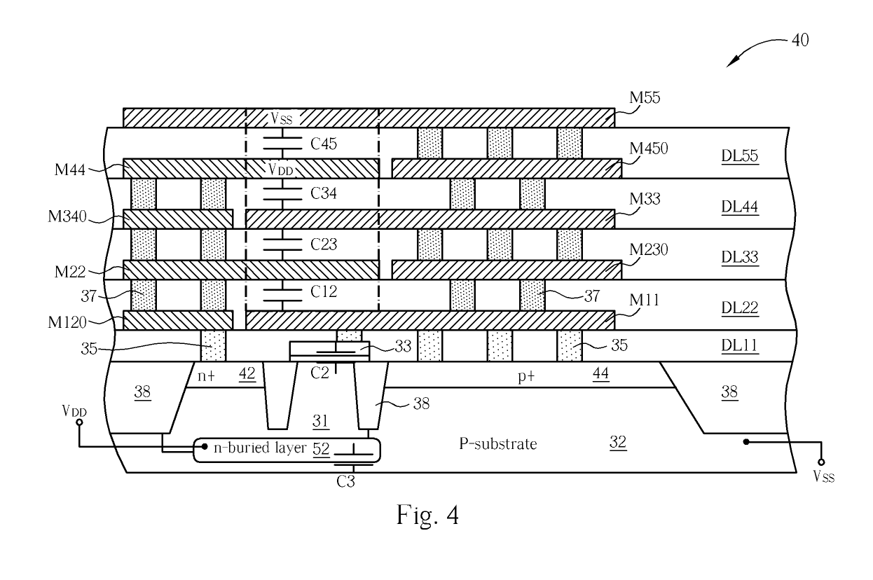

Please refer to FIG. 4 that is a cross-sectional drawing of another seal-ring structure 40 according to the present invention. The composition of the seal-ring structure 40 is similar to the composition of the seal-ring structure 30. The difference between the seal-ring structure 40 and the seal-ring structure 30 is that the seal-ring structure 40 further includes an n-buried layer 52 formed between the n-well 31 and the p-substrate 32. A third capacitor C3 is formed between the n-buried layer 52 and the p-substrate 32 because the n-buried layer 52 is connected to the second voltage terminal V_{DD} and the p-substrate 32 is connected to the first voltage terminal V_{SS}. The doped concentration of the n-buried layer 52 is greater than the doped concentration of the n-well 31.

Please continue to refer to FIG. 4. The capacitors C12, C23, C34, and C45 are capacitors formed between two metal layers in which one metal layer is connected to the first voltage terminal V_{SS} and another metal layer is connected to the second voltage terminal V_{DD}. The capacitance of these capacitors is small because the thickness of oxide layer between two metal layers is quite thick. Take an IC of 14000×1000 size for example; the total capacitance between two metal layers can reach 40 pF. The second capacitor C2 is formed between the poly-silicon layer 33 and the n-well 31 where the internal oxide layer is quite thin. Take an IC of 14000×1000 size for example; the capacitance of the second capacitor C2 can reach 20 pF. The third capacitor C3 is formed between the n-buried layer 52 and the p-substrate 32. There is a junction capacitor formed since a depletion region is generated between the n-buried layer 52 and the p-substrate 32 due to its reverse bias.

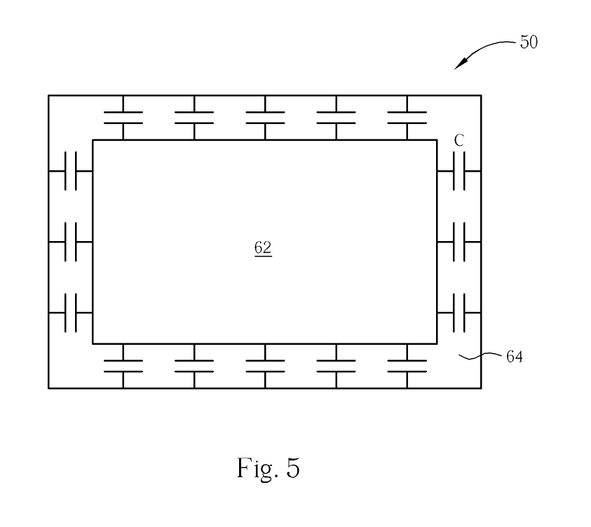

Please refer to FIG. 5. FIG. 5 is a diagram of an integrated circuit chip 50 with a seal-ring structure according to the present invention. The integrated circuit chip 50 includes an internal wafer 62. A circle of seal-ring structure 64 is added around the internal wafer 62 to protect the internal wafer 62. The seal-ring structure 64 can be the seal-ring structure 30 or 40 mentioned in embodiments of the present invention. There is a plurality of de-coupling capacitors C generated in the seal-ring structure 64 to regulate power.

The above-mentioned embodiments illustrate but do not limit the present invention. The base of the seal-ring structure is not restricted to a p-substrate as it could be an n-substrate. The number of metal layers is not limited to five layers; it depends on user's demand. The arrangement manner of metal layers is not restricted to the embodiments of the present invention.

In conclusion, the present invention provides seal-ring structures 30 and 40 with system-level ESD protection. Connecting the n+ highly doped region 42 (or the n-well 31) to the highest voltage V_{DD} and connecting the p+ highly doped region 44 (or the p-substrate 32) to the lowest voltage V_{SS} can improve ESD protection. Skilled use of layout can improve capacitance between two metal layers. This helps stabilizing power and improving ESD protection. Furthermore, adding the poly-silicon layer 33 between the first metal layer M11 and the n-well 31 forms the second capacitor C2 between the poly-silicon layer 33 and the n-well 31 where the internal oxide layer is quite thin. The n-buried layer 52 is formed between the n-well 31 and the p-substrate 32 to improve integrated circuits from ESD damage.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A seal-ring structure for system-level ESD protection formed on a p-substrate which is coupled to a first voltage terminal, the seal-ring structure comprising:
an n-well formed on the p-substrate, the n-well coupled to a second voltage terminal;
a first metal layer including a portion of a block sited on a first dielectric layer on the p-substrate and connected to the p-substrate through a plurality of contacts;
a second metal layer including a portion of a block sited on a second dielectric layer on the first metal layer and connected to the n-well through a plurality of contacts;
a first capacitor formed between the first metal layer and the second metal layer;
a poly-silicon layer formed between the first metal layer and the n-well; and
a second capacitor formed between the poly-silicon layer and the n-well.

2. The seal-ring structure of claim 1 further comprising an n-buried layer formed between the n-well and the p-substrate.

3. The seal-ring structure of claim 2 further comprising a third capacitor formed between the n-buried layer and the p-substrate.

4. The seal-ring structure of claim 2 wherein the doped concentration of the n-buried layer is greater than the doped concentration of the n-well.

5. The seal-ring structure of claim 1 further comprising an n+ highly doped region formed on the n-well, the n+ highly doped region is coupled to the second voltage terminal.

6. The seal-ring structure of claim 5 wherein the second metal layer is coupled to the n+ highly doped region through the plurality of contacts.

7. The seal-ring structure of claim 5 wherein the doped concentration of the n+ highly doped region is greater than the doped concentration of the n-well.

8. The seal-ring structure of claim 1 further comprising a p+ highly doped region formed on the p-substrate, the p+ highly doped region coupled to the first voltage terminal.

9. The seal-ring structure of claim 8 wherein the first metal layer is coupled to the p+ highly doped region through the plurality of contacts.

10. The seal-ring structure of claim 8 wherein the doped concentration of the p+ highly doped region is greater than the doped concentration of the p-substrate.

11. The seal-ring structure of claim 8 further comprising a dielectric isolation layer formed between the p+ highly doped region and the n-well.

12. The seal-ring structure of claim 11 wherein the dielectric isolation layer is silicon dioxide (SiO₂).

13. The seal-ring structure of claim 1 wherein the first voltage terminal is a lowest voltage of the seal-ring structure (V_{SS}).

14. The seal-ring structure of claim 1 wherein the second voltage terminal is a highest voltage of the seal-ring structure (V_{DD}).

15. The seal-ring structure of claim 1 further comprising a third metal layer, the third metal layer coupled to the first metal layer through a plurality of vias.

16. The seal-ring structure of claim 15 further comprising a fourth capacitor formed between the third metal layer and the second metal layer.

17. The seal-ring structure of claim 16 further comprising a fourth metal layer, the fourth metal layer coupled to the second metal layer through a plurality of vias.

18. The seal-ring structure of claim 17 further comprising a fifth capacitor formed between the fourth metal layer and the third metal layer.

19. The seal-ring structure of claim 18 wherein the first metal layer, the second metal layer, the third metal layer, and the fourth metal layer include gold.

20. The seal-ring structure of claim 18 wherein the first metal layer, the second metal layer, the third metal layer, and the fourth metal layer include copper.
